(19) United States
(12) Patent Application Publication
(10) Pub. No.: US 2008/0213738 A1
(43) Pub. Date: Sep. 4, 2008

(54) Electronic Circuit Experiment Board

(76) Inventor: Rongchang Li, Guangdong (CN)

Correspondence Address: GLOBAL IP SERVICES, 7285 W. Eagle Court, Winton, CA, 95388, US

(21) Appl. No.: 11/916,091

(22) PCT Filed: May 31, 2006
(86) PCT No.: PCT/CN2006/001169

§ 371 Date: Nov. 30, 2007

(30) Foreign Application Priority Data
May 31, 2005 (CN) 200520109262.8

(51) Int. Cl. G09B 23/18; H05K 7/10

(52) U.S. Cl. 434/301; 361/730

(57) ABSTRACT

The present invention is an electronic circuit experiment board, which is composed of an insulated base plate, copper binding posts and a bracket and so on. The base plate is divided into an upper plate and a lower plate, which have binding post inserting holes and circlips. The binding posts can be inserted into the binding post inserting holes and then be fastened by the circlips. There are a binding hole and a screw hole on the ends of the binding posts respectively. The binding post also includes a screw lever cooperated with the screw hole, a positioning groove and a positioning ring. The experiment board has the advantages of good contact performance, convenient to use, high experimental efficiency, long service life and strong ability of splicing and dilatancy, arranging elements in double sides, and multilayer wiring in electronic circuit.

### BACKGROUND OF THE INVENTION

1. Field of the Invention

The present invention relates to an experimental apparatus for the electronic circuit, especially relates to the improvement of the electronic circuit experiment board.

2. Description of the Prior Art

The currently used experimental apparatus for the electronic circuit has lots of deficiency which is as follows:

1. Experimental Table of Electronic Circuit

The experimental table of the electronic circuit in laboratories has the following demerits.

a. We use four plugs and jacks in experimental table to replace the intersection point of four lines in electrical circuit while using the plug wiring mode of elastic contact. According to experiment rules there is only one potential in the same point, while the different potential often appears because of the contact failure to different extent between four plugs and jacks in actual experiment, which leads to failure of experiments.

b. The design of large mesa structure increase the experiment cost and reduce the teaching effect, because students' practical chance in the based-on-team organization of experiment is insufficient, and the individuation creativity in the procedures and results of the experiment is difficult to exert.

c. Less link points for circuit connection can't support the complex experiment.

d. Special plug and wire cause high cost, and it's impossible to adjust the length of wire, which results in the confusion of wiring system and poor visual impression.

2. The Bread Board

The bread board was introduced from abroad, and has the advantage of high connection speed on wiring access. It has the arrangement of five jacks allocating in a row outside the same interconnect point of the wire, but one spring lamination inside the bread board, which results in the confusion of wiring system and poor visual impression. Furthermore, the phenomenon of simultaneous contact failure of multi-point often appears in the process of inserting some straight or curved wiring with irregular round simultaneously in the same spring lamination because the elastic contact method of the connecting wiring still be used, which increases the difficulty of failure query, and lead to the interruption of experimental procedure finally. In sum, the experimental apparatus for the electronic circuit which adopt the elastic contact method of wiring connection have some weakness of contact failure, lack of vibration-proof ability, and the poor durability.

3. The Experiment Board of Printed Circuit on Double Sides

The experiment board of printed circuit on double sides is mainly prevalent in electronic amateur and electronic scientific research units. It is inconvenient to connect wiring by means of welding, and the method is difficult to use for beginners and students of primary and middle school, which cause the low efficiency of the experiment. Meanwhile, the problems of false welding and short circuit, which frequently encountered in the experiment shorten the service life, because of the confusion of wiring system.

4. Special Experimental Device

The special experimental device which is designed in factory according to the teaching brief and teaching content was used in laboratory of some specialized cademies and vocational schools, but its main defect is apt to be the bad universal use and high investment, so the experimental device will be eliminated once setting new major and renewing contents of the textbook because of the rapid speed of the development of electronic technology, electronic components of new generation and the variation of talents demand along with the development of market economy. Therefore, the service life of general experimental device was very short, which will bring more risks of the investment.

Besides, it has some disadvantages in experiment such as lack of ability in splicing and dilatancy, arranging elements in double sides, and multilayer wiring in the existing experimental equipment and apparatus for the electronic circuit

Therefore, it is quite necessary to provide a new kind of general experimental board for electronic circuit which has the advantages of good contact performance, strong visual impression, high experimental efficiency, long service life and strong ability of growth.

### SUMMARY OF THE INVENTION

One object of the present invention is to provide a kind of general experimental board for electronic circuit which has the advantages of good contact performance, strong visual impression, high experimental efficiency, long service life and strong ability of growth, comprising

An electronic circuit experiment board is composed of an insulated base plate and copper binding posts. The base plate have binding post inserting holes and circlips. The copper binding posts can be inserted into the binding post inserting holes and then be fastened by the circlips. There are a binding hole and a screw hole on the ends of the binding posts, respectively. The binding post also includes a positioning groove, a positioning ring, and a screw lever cooperated with the screw hole.

The base plate of the electronic circuit experiment board is divided into an upper plate and a lower plate. There are circlip grooves setting in the position of binding post inserting holes, and the circlips are fixed in the circlip grooves. The electronic circuit experiment board also includes a handling lever, and the base plate includes handling lever inserting holes as well. The handling lever can be inserted into the handling lever inserting holes and then open the circlips to help inserting the binding posts.

The base plate is also divided into an upper plate, a lower plate, and an intermediate nylon slice which includes nylon circlips. There are circlip holes in the upper plate, and the nylon locating circlips is fixed in the circlip holes.

The base plate also includes binding posts coding for the convenience of double sides wiring.

The electronic circuit experiment board also includes accessories, which includes bracket, splicing card, and component composite plate. The bracket includes integrated circuit board, motion arm, and pedestal bearing fixed or flexible. The splicing card includes T-shaped card and cross-shaped card. The component composite plate includes component, five-hole binding posts (screw lever appended), printed circuit board, plate seat, and conical prong (screw appended).

The present invention use double sides binding posts which can be inserted whenever used, so it has the advantages of good contact performance, strong visual impression, high experimental efficiency, long service life and strong ability of splicing and growth, arranging elements in double sides, and multilayer wiring in electronic circuit.

### BRIEF DESCRIPTION OF THE DRAWINGS

FIG. 1 is the schematic diagram of the electronic circuit experiment board.

FIG. 2 is the partial enlarges profile diagram of section I in FIG. 1.

FIG. 3 is the structural diagram of the fixed pedestal bearing.

FIG. 4 is the structural diagram of the flexible pedestal bearing.

FIG. 5 is the structural diagram of the splicing card.

FIG. 6 is the splicing diagram of the electronic circuit experiment board.

FIG. 7 is the schematic diagram of the component composite plate.

FIG. 8 is the schematic diagram of the electronic circuit experiment board in the other embodiment.

FIG. 9 is the schematic diagram of the electronic circuit experiment board in another embodiment.

### DETAILED DESCRIPTION OF THE INVENTION

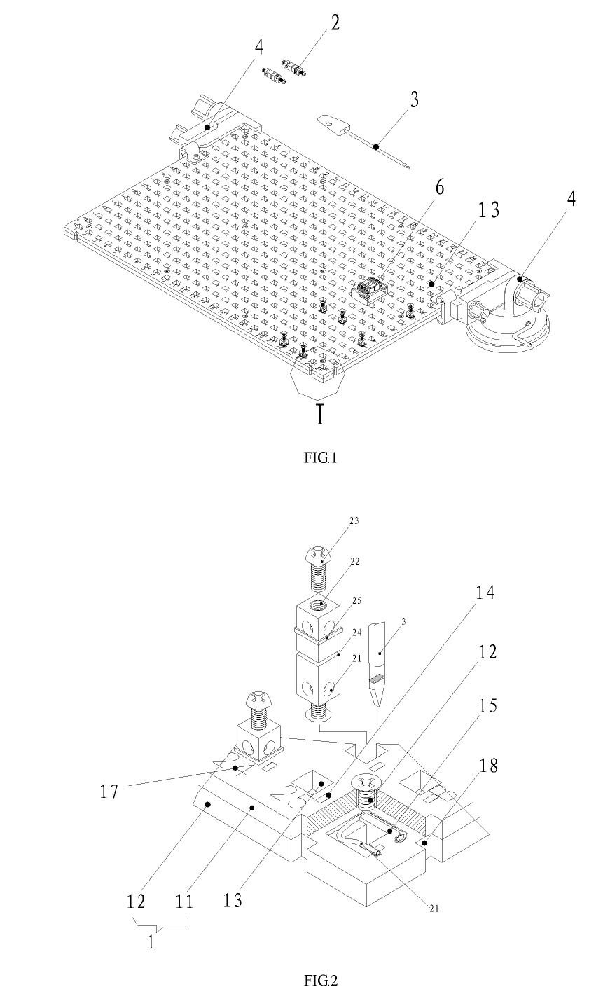

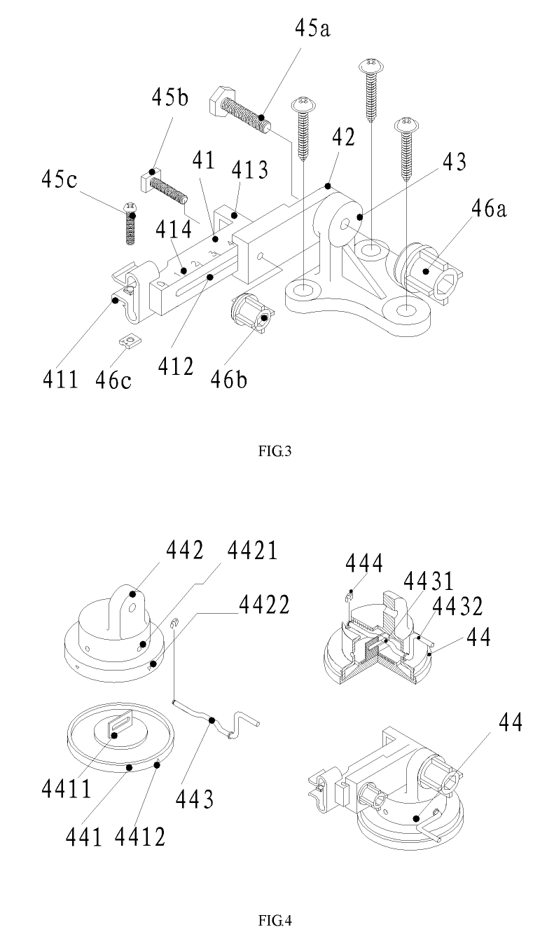

FIG. 1 and FIG. 2 are the references for the embodiment. The electronic circuit experiment board in the present invention is composed of an insulated base plate 1 and a plurality of binding posts 2, and the base plate 1 is divided into an upper plate 11 and a lower plate 12 which includes a plurality of binding post inserting holes 13 corresponding with the upper plate and the lower plate respectively. The binding posts 2 can be inserted into the binding post inserting holes 13. There are four binding holes 21 in the lateral face of the binding posts 2 which close to two ends. There are a screw hole 22 on the ends of the binding posts respectively, and the screw hole 22 are connected with the binding holes 21 that lies in the same side. The practical cross section of the binding posts in the binding holes get up to the mechanical strength demands. The binding posts 2 also includes a screw lever 23 cooperated with the screw hole 22. The conductor was inserted into the binding posts 21, then wring the screw lever 23 to press the conductor in the process of installation and connection.

The electronic circuit experiment board also includes a handling lever 3 and multiple handling lever inserting holes 14 which distributed in the side of binding post inserting holes 13 upper and lower respectively in the upper plate 11 and the lower plate 12. The handling lever 3 can be inserted into the handling lever inserting holes 14. There is an inclined plane 31 in one side of the handling lever 3. The electronic circuit experiment board also includes circlips 16 and circlip grooves 15 which lies in the position of binding post inserting holes 13 in the upper surface of the lower plate 12. The circlip grooves 15 is partly open. The circlips 16 is fixed at one end into the circlip grooves 15, and the other end partly screen the binding post inserting holes 13 and the handling lever inserting holes 14. The circlips have the characteristic of elastic expansion.

The binding post 2 also includes positioning groove 24 and positioning ring 25. The positioning groove 24 is a ring groove setting in the middle of the binding post 2. The cross section of the binding posts in the positioning groove 24 get up to the mechanical strength demands. The positioning ring 25 is a ring flange located in the upper of the positioning groove 24. The distance between the positioning groove 24 and the binding post 2 is corresponding to the upper plate 11. When the binding post 2 was inserted into the binding post inserting holes 13, the 45° chamfer inclined plane in the lower end of the binding post can push away the circlip automatically, and the positioning ring 25 block in the surface of the upper plate 11, meanwhile, the elastic expansion end of the circlip 16 insert into the positioning groove 24 to fasten the binding post. When the binding post 2 needs to be pull out, the handling lever 3 is inserted into the handling lever inserting holes 14, then the horizontal component of force produced in inclined plane 31 in the lower end of the handling lever push the circlip 16 open and loosen the locking state, which make the binding post 2 pull out smoothly.

The upper plate 11 and the lower plate 12 are fixed with screw. The upper plate 11 includes countersunk holes, and the lower plate 12 has the screw holes. There are two positioning lever (unlabeled) in the lower part deviated center of the upper plate 11, and two positioning holes (unlabeled) setting in the upper part of the lower plate 12 respectively. The codes 17 in the same arrangement can be set in the edges of the base plate 1 with double-sides, or located in the position of each binding post inserting holes 13. There are circlip grooves 18 in the corner of the base plate 1 for the use of setting bracket to support the base plate in lateral direction or vertical direction. The base plate 1 can be made with organic glass material which has superior performance such as good crack resistance, long age resistance, high optical transmittance, high electrical insulating, dimensional stability, corrosion resistance, and secondary processability. Therefore, the base plate 1 has the advantages of firm and durable performance, stable performance, bright and transparency, low cost in manufacture and use, and long service life.

The square circlip grooves 15 is set with horizontal direction in the position of binding post inserting holes 13 which lies in the upper surface of the lower plate 12. There are circlips 16 of special-shaped stainless steel wire orientation in the circlip grooves. The main effect of the circlips 16 is locking the binding post 2, which stop the binding post 2 slipping into the other side when rotate the screw lever 23 of the binding post from the back of the experimental board. Each side of the circlips 16 lies in the same plane tightening inward in free state, while a section of circlips 16 will insert into the positioning groove 24 of the binding post 2 in labour hour. The apparatus has the advantage of reliable location and accord with the requirements of strength. The material of stainless steel could be selected to make circlips 16, which can prevent the pollution of corrosion in the experiment board, and improve the insulation property.

The metal part of the handling lever 3 is made of stainless steel wire, which has the cylindrical part in the upper, the flat part in the lower, and the isosceles triangle inclined plane 31 in the end of the lower part. The horizontal component generated from the inclined plane 31 will push the circlips 16 open. The tip of the handling lever is blunt after special treatment, which can prevent injury of hands. The juncture of the upper and the lower part make the location role, that is the binding post 2 can be pull out once insert into the right position. The handle part of the handling lever designed to flat streamlined shape with thin section in the upper and thick section in the lower is made of plastic, which is different with screwdriver.

With the reference of FIG. 3 and FIG. 4 the electronic circuit experiment board also includes a bracket 4, which is composed of integrated circuit board 41, motion arm 42, and pedestal bearing. There is a runner (unlabeled) in the motion arm 42 to accept integrated circuit board 41. The connection among the integrated circuit board 41, motion arm 42, and the pedestal bearing is fixed with the fitting between the screw lever 45a, 45b and nut 46a, 46b. The integrated circuit board 41 includes elastic clip 411 and strip hole runner 412, and the elastic clip 411 is used to retain the experiment board, which can be further fixed with screw lever 45c and nut 46c. The distance between the boards of the elastic clip 411 in free state is shorter than the thickness of the experiment board. The strip hole runner 412 allow the screw lever 45b to glide in it, which make the runner of the integrated circuit board 41 has a flexible scope along the motion arm 42. The integrated circuit board 41 also includes the backup 413 and locating electric circuit experiment board. It has scales in the integrated circuit board 41 for the use of comparing with the left and right to make the flexible quantity with one accord. The cuboid motion arm 42 can make the experiment board turnover or fix in the position with any degree, which has a runner (unlabeled) ahead fitting with the integrated circuit board 41, and a semi-circle back end connected with pedestal bearing using screw lever 45a, and the end deep into the side incline of the motion arm while not preventing the flexible moving of the integrated circuit board.

The pedestal bearing of the bracket 4 includes fixed type and flexible type on the basis of the actual requirement. The fixing pedestal bearing 43 includes a bias triangle base with fillet which has three rotundums cooperated with three screws pinning to the table top. The head of horrizm fulcrum bar in superior extremity is cylindrical with rotundum in center. The total width of the experimental facility can be diminished if place the fixing pedestal bearing 43 in opposition, because the use of the bias triangle base, which is suitable to fix in small experiment case. The flexible pedestal bearing 44 includes negative pressure sucking disk 441, backstop 442, and pusher 4431. The negative pressure sucking disk 441 is made of rubber, which is thin surrounding and thick in center, and set a metal button 4411 with strip hole in the center of the disk. There are two symbols for orientation in both sides of the lateral edges exactly right to the strip hole. There are four holes 4421 in flank of the circular platform backstop 442, which can provide selection of four kinds of inserting direction of the pusher 443. There are four symbols 4422 exactly right to each hole, which is used to locate the strip hole of the metal button 4411 setting in the negative pressure sucking disk 441. There is a semi-circle end cuboid fulcrum bar in the backstop 442 biasing one side, which retain the rotation space of the plastics nut by hand. The pusher 443 including bent axle 4431 and bat-handle 4432 is designed according to the lever principle, in which the foothold is the hole 4421 in the side of backstop 442, the bending direction of bent axle 4431 and bat-handle 4432 is vertical, the bent axle 4431 is locked by bolt reed 444 in lateral of the backstop 442 after cutting through the rotundum 4421 in bilat of the backstop 442 and the strip hole in the metal button 4411 subsequently, and the offset of the force arm of bent axle 4431 is smaller than that of the bat-handle 4432.

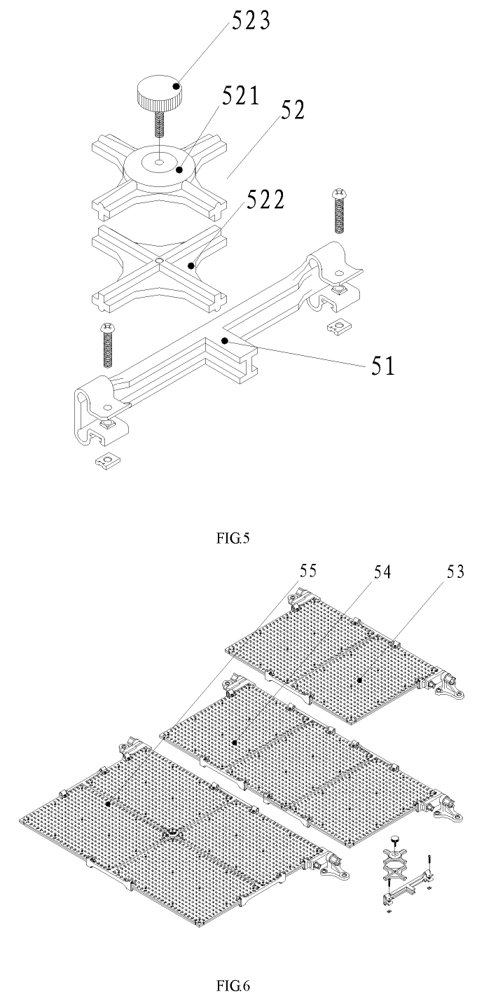

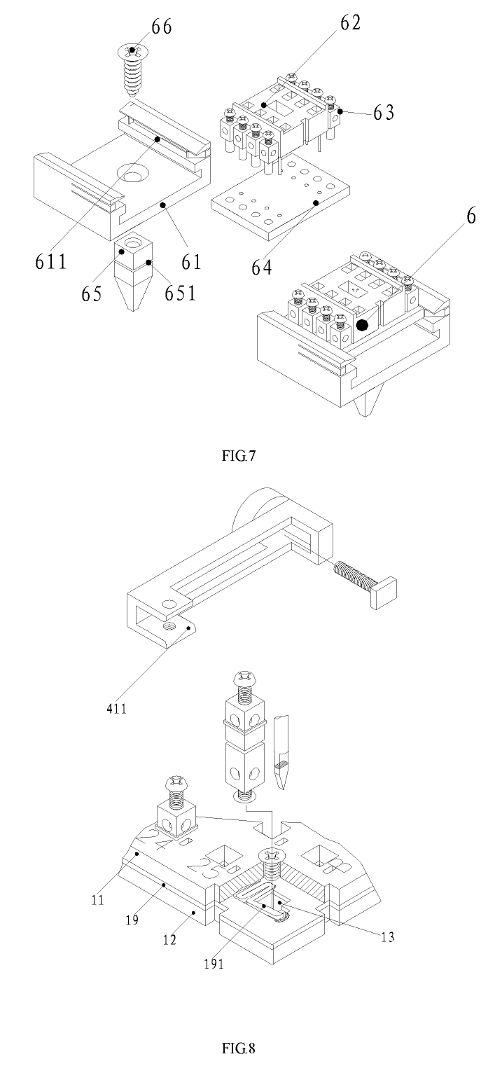

It can also splice many experiment board together using splicing card 5 according to the in -service use, with the references of FIG. 5 and FIG. 6. The splicing card 5 includes T-shaped splicing card 51 and cross-shaped splicing card 52. The shape of T-shaped splicing card 51 can disperse the strength of the junction, which has elastic clips 511 in ends, and the structure and effect is the same with the elastic clip in integrated circuit board of the bracket 4. The cross-shaped splicing card 52 includes the upper card 521, the lower card 522, and screw lever 523, and the shape of the upper card 521 is coincident with the lower card 522. For the purpose of increasing intensity, the four-end of the card is narrow and thin, and the shape of the cross section is crux, which is broad and thick in center and cross to the circular platform. The splicing center of four basal plates can be combined together with the upper card 521 and the lower card 522 through the screw lever 523, that is it can put splicing card together to form all kinds of splice plate such as di-splice plate 53, tri-splice plate 54, tetra-splice plate 55 and multi-splice plate (unshown in drawing).

For the purpose of increasing the utility of bracket 4 and splicing card 5, the distance between the binding post inserting holes 13 in surrounding of the base plate 1 and the edge line of the experiment board is equation.

FIG. 7 is the resolving and packing schematic diagram of the component composite board 6 in process of decomposing and assembling. The component composite board 6 includes the plate seat 61, the multipolar component 62, the binding post 63, printed circuit board 64, and connector pin 65. The plate seat 61 is sulciform, which has the runner 611 in both sides. It has the block claw (unlabeled) in two ends of the runner, and the block claw in one side has elasticity, which make the printed circuit board sliding in and out convenient. The space setting in the lower part of the plate seat 61 can accept the solder side of the printed circuit board. The backboard (unlabeled) is under the plate seat, which has the rotundum (unlabeled) placing the screw 66 in the center of the plate seat. The binding post 63 has four inserting holes, and the lower end is a circular cylinder foot. Each electrode of the multipolar component 62 correspond to each binding post 63 with the corresponding numbers respectively. The multipolar component 62 and the binding post 63 are welded in the printed circuit board 64 designed and manufactured before. There are screw holes (unlabeled) matching to the screw 66 in the top of the connector pin 65, and there are ring form location notch 651 in the upper part of the connector pin 65. The depth of the location notch 651 is lower than the radius of the circlips 16 in binding post inserting holes 13, so the location notch 651 matching with the circlips 16 in binding post inserting holes 13 of the experiment board make partly orientating function to the connector pin 65. The connector pin 65 of the component composing board 6 can be set with one or more than according to the demand, and the space of the connector pins is the same with the space of the binding post inserting holes 13 in the experiment board.

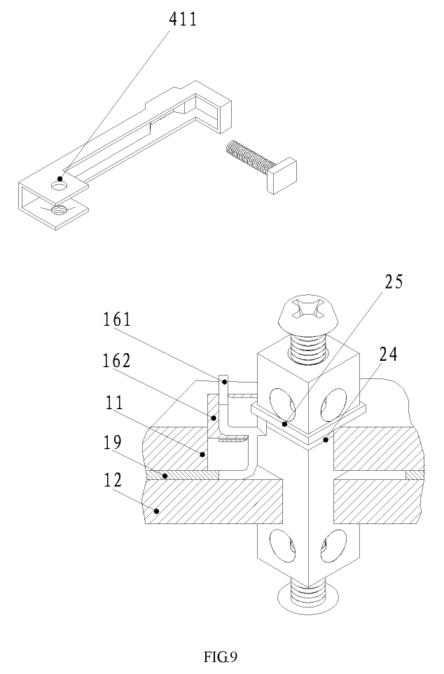

With the reference of FIG. 8, the other example of the electronic circuit experiment board in the present invention is that the base plate adopt two pieces of epoxy resin board, and the size of the board and the parameter of the binding post inserting holes and the handling lever holes maintained invariably. There is no circlip groove in the middle of the board, and have no stainless steel circlips, but have a intermediate plate 19 using nylon material. There are nylon circlips 191 closing to the binding post inserting holes 13, which is integrated with the intermediate plate 19, and slightly thinner than the intermediate plate 19. It is that not only reduce the cost, but also reduce the trivial process fixing the circlips and improve the holistic insulation property. The elastic clip 411 of the integrated circuit board 41 of the bracket 4 in this example is changed to plane clip pinning with screw, and the elastic clip 511 of the T-shaped splicing card 51 is changed in the same way. The design of the bracket has no runner, no motion arm 42, but connect the back end of the integrated circuit board 41 with the pedestal bearing. For the purpose of increasing the friction force the junction in the back end of the integrated circuit board 41 is designed to round platform, and the cuboid screw head hide into the groove of the integrated circuit board, but the pedestal bearing maintain the same. The ability of the supporting and inverting in this example is not changed, and flexible function is decreased, which reduce the cost greatly.

With the reference of FIG. 9, another example of the electronic circuit experiment board in this present invention is that the base plate 1 is composed of two pieces of epoxy resin board or organic glass board, and a nylon intermediate plate 19. The size of the board and the binding post holes is the same with the example before, but without handling lever holes. The structure of three pieces of board is different with each other. The lower board 12 only has the binding post inserting holes 13 with the improved strength. The nylon intermediate plate 19 in the middle pass through the nylon locating circlips 161 with protruding in inclined plane by clipping, and the direction of locating circlips 161 is the same with the direction of the diagonal of the binding post inserting holes 13. The shift lever lies in the top of the circlip, so the binding post can be taken out by turning nylon circlip with nail or breaker. When making the binding post inserting holes 13 in the upper board 11, we can make a rectangle circlip hole (unlabeled) in the 45 dimension along the lateral of the binding post inserting holes 13 at the same time. Put the holes together to make the nylon locating circlips 161 inside the circlip holes, and leave activity space 162 behind the shift lever. The position of the toroid positioning groove 24 in the middle of the binding post 2 hug to the positioning ring 25. The toroid positioning groove of the connector pin in the component composite plate 6 is canceling correspondingly(unshown in figure). The integrated circuit board 41 of the bracket 4 in the example is produced with stainless steel by punching and shearing, the T-shaped splicing card 5 is produced in the same way. The elastic clips 411 and elastic clips 511 is changed to the plane clips fixing with screw. Open rotundum in the upper clip, and open screw holes in the lower clip after punching to claw downward. Cancel the sliding groove and the motion arm, and connect the back end of integrated circuit board 41 with the pedestal bearing. The screw hide in the drop pit of the back end punching outward. For the purpose of increasing friction there are hard rubber septum inspissating between the integrated circuit board 41 and the fulcrum bar head of the pedestal bearing, and the pedestal bearing maintain the same.

What is claimed is:

1. An electronic circuit experiment board, comprising an insulated base plate and copper binding posts, wherein said base plate has binding post inserting holes and circlips, said binding posts can be inserted into said binding post inserting holes and then be fastened by said circlips, a binding hole and a screw hole are formed on the ends of said binding posts, respectively, and said binding post also includes a screw lever cooperated with said screw hole.

2. The electronic circuit experiment board of claim 1, wherein a shape of said binding post is long strip, a positioning groove is defined in a middle of said binding post, and a positioning ring is formed in an upper end of said positioning groove.

3. The electronic circuit experiment board of claim 1, wherein said base plate includes an upper plate and a lower plate, which connected with each other.

4. The electronic circuit experiment board of claim 1, wherein said base plate further includes circlips mounted in the position of said binding post inserting holes.

5. The electronic circuit experiment board of claim 1, wherein it further includes a splicing card for splicing a plurality of said experiment boards together.

6. The circuit experiment board of claim 5, wherein said splicing card includes a T-shaped card and a cross-shaped card.

7. The circuit experiment board of claim 1, wherein a coding of said binding post is defined on the base plate.
